(19) United States
(12) Patent Application Publication
(10) Pub. No.: US 2023/0191554 A1
(43) Pub. Date: Jun. 22, 2023

(54) POLISHING SYSTEM

(71) Applicant: Konica Minolta, Inc., Tokyo (JP)

(72) Inventors: Atsushi TAKAHASHI, Kokubunji-shi, Tokyo (JP); Akihiro MAEZAWA, Hino-shi, Tokyo (JP); Fumiko TSUKIGATA, Hino-shi, Tokyo (JP); Keisuke MIZOGUCHI, Hachioji-shi, Tokyo (JP)

(21) Appl. No.: 17/921,391

(22) PCT Filed: Apr. 12, 2021
(86) PCT No.: PCT/JP2021/015173

§ 371 Date: Oct. 26, 2022

(30) Foreign Application Priority Data
Apr. 27, 2020 (JP) 2020-078132

(51) Int. Cl. B24B 37/013

(52) U.S. Cl. CPC B24B 37/013

(57) ABSTRACT

A polishing system performs chemical-mechanical polishing of an object to be polished using an abrasive slurry. The polishing system includes a polishing amount calculator that measures an amount of free metal ions of a metallic element derived from the object to be polished in a processed slurry and calculates a polishing amount of the object to be polished from the amount of the free metal ions. The object to be polished is a glass containing the metallic element of Group 1 or Group 2 of a periodic table.

### TECHNICAL FIELD

The present invention relates to a polishing system. More specifically, the present invention relates to a polishing system that enables simple and precise measurement of a polishing amount of an object to be polished.

### BACKGROUND ART

In a precise polishing process of glass, a rare earth oxide such as cerium oxide is used as an abrasive. The polishing process using cerium oxide is used in a finishing process of a wide variety of products, such as optical glass, cover glass for a smartphone, and cover glass for an in-vehicle display.

In the polishing process of glass, the cerium oxide abrasive is generally used in the following manner. While a polishing cloth or brush is pressed against the glass, pressure is applied to a slurry of cerium oxide fine particles dispersed in water or the like such that relative movement is made. Thereby, the polishing process is performed. The speed of the polishing process and the quality of the finished surface are affected by various factors, such as pressure during the process, relative moving speed, temperature of the processed surface, properties of the slurry, properties of the polishing cloth or brush, and the like. Since these factors change from time to time, it is not easy to obtain the same processing quality for each and every polishing process.

In the polishing process, the polishing amount (thickness) is required to be strictly controlled. For optical glass, polishing needs to be carried out with precision of within plus or minus a few micrometers in a process of several tens of micrometers. When the polishing amount is not enough, the process needs to be performed again, which reduces the throughput of the processes. On the contrary, when the polishing amount exceeds the specification value, the processed glass is discarded as a defective product.

Efforts have been made to evaluate the polishing amount (thickness) physically and in real time (see, for example, Patent Literature 1 and Patent Literature 2). However, evaluating the polishing amount with precision of a few micrometers has been difficult because of the following reasons.

In the polishing process, as described above, the glass to be polished is sandwiched between an upper surface plate and a lower surface plate to which a polishing cloth or the like is attached and is pressed by pressure applied to the upper surface plate and the lower surface plate while the abrasive slurry is supplied, and the upper and lower surface plates are rotated in relative directions. The polishing cloth used here is generally a sheet of synthetic resin foam of one to several millimeters in thickness made of a foamed material such as urethane, which is compressed and deformed by the pressure from the upper and lower surface plates.

In the polishing process, the distance between the upper surface plate and the lower surface plate of the polishing machine does not correspond to the thickness of the polished glass because the elasticity of the polishing cloth changes under the influence of the flowing slurry and the heat generated in the polishing process.

Therefore, it is difficult to control the polishing amount of glass even when the distance between the upper and lower surface plates of the polishing machine is controlled by using a machine with high precision. It is also difficult to precisely evaluate the polishing amount of glass even when the distance between the upper and lower surface plates is measured by, for example, an eddy-current film thickness meter.

Furthermore, the abrasive slurry used for a glass polishing process is not usually flowed freely but is repeatedly used for polishing processes and then replaced to be discarded. It is known that an increase in the concentration of a glass component(s) in the abrasive slurry resulting from the polishing process reduces the speed of the polishing process and the finishing quality.

For this reason, the abrasive slurry is replaced with a new one after being used for a certain number of times. It is difficult to measure the amount of the glass component in the abrasive slurry onsite, simply, and in a short time. Therefore, the abrasive slurry is replaced, for example, once in two weeks to once a month. The amount of the glass component in the abrasive slurry differs depending on the polishing machine used. Therefore, at the time of replacement, some slurries may have too much glass component and be unsuitable for the polishing process, while others may have a small amount of the glass component and be discarded even though they do not need to be replaced yet. This is unfavorable from the perspectives of both quality improvement of the polishing process and the efficient use of the abrasive.

In order to evaluate the condition of the slurry, ICP (Inductively Coupled Plasma) atomic emission spectrometry (also referred to as “ICP-AES”) and the like has been used to quantify the elements contained in the slurry (see, for example, Patent Literature 3 and Patent Literature 4). However, since the analysis is time-consuming, it is not yet possible to understand the polishing amount of the object to be polished on the manufacturing site, in a short time, simply, and precisely.

### CITATION LIST

### Patent Literature

[Patent Literature 1] JP 2006-231470 A
[Patent Literature 2] JP 2006-231471 A
[Patent Literature 3] JP 5370598 B2
[Patent Literature 4] WO 2013/122123 A1

### SUMMARY OF INVENTION

### Technical Problem

The present invention was made in view of the above problems and circumstances, and the problem to be solved is to provide a polishing system that enables simple and precise measurement of the polishing amount of the object to be polished.

### Solution to Problem

In order to solve the above problems, the inventors of the present invention have examined the causes of the above problems and the like. As a result, it was found that, when cerium oxide is used as an abrasive to polish glass, components other than silicon, in particular, a metallic element of Group 1 or 2 of the periodic table, are released into the slurry as free metal ions after the polishing process. Furthermore, it was found that, as the polishing amount increases, the concentration of these ions increases almost proportionally to the polishing amount of glass. Therefore, it was found that to be possible to measure the polishing amount, that is, the amount of glass having been polished, in a short time and with high precision by measuring free metal ion concentration in the abrasive slurry.

Furthermore, the phenomenon that not only the free metal ion concentration in the processed slurry but also the electrical conductivity increased almost proportionally to the polishing amount was recognized, which led to the present invention.

In other words, the above problems related to the present invention are solved by the following means.

1. A polishing system that performs chemical-mechanical polishing of an object to be polished using an abrasive slurry, the polishing system including:
a polishing amount calculator that measures an amount of free metal ions of a metallic element derived from the object to be polished in a processed slurry and calculates a polishing amount of the object to be polished from the amount of the free metal ions,
wherein the object to be polished is a glass containing the metallic element of Group 1 or Group 2 of a periodic table.

2. The polishing system according to item 1, wherein an endpoint of polishing is determined based on the polishing amount of the object to be polished.

3. The polishing system according to item 1 or 2, wherein a time of discarding the abrasive slurry is determined based on the polishing amount of the object to be polished.

4. The polishing system according to any one of items 1 to 3, wherein the free metal ions derived from the object to be polished are free metal ions of a metallic element of Group 1 of the periodic table.

5. The polishing system according to any one of items 1 to 4, wherein the free metal ions derived from the object to be polished are sodium ions or potassium ions.

6. The polishing system according to any one of items 1 to 5, wherein the abrasive slurry contains cerium oxide.

7. A polishing system that performs chemical-mechanical polishing of an object to be polished using an abrasive slurry, the polishing system including:
a polishing amount calculator that measures a conductivity of a processed slurry and calculates a polishing amount of the object to be polished from the conductivity,
wherein the object to be polished is a glass containing a metallic element of Group 1 or Group 2 of a periodic table.

### Advantageous Effects of Invention

The above means of the present invention can provide a polishing system that enables simple and precise measurement of the polishing amount of an object to be polished.

The expression mechanism or action mechanism of the effect of the present invention has not been clarified but is inferred as follows.

As the amount of the glass component in the processed abrasive slurry increases, that is, as the polishing amount increases, it is observed that the conductivity and ion concentration of the abrasive slurry increase almost proportionally to the polishing amount.

From this phenomenon, we presume that the object to be polished (glass) is not solid but in a dissolved state in the polishing process using cerium oxide, and the metallic element of Group 1 or 2 of the periodic table, which is a component other than silicon in the glass before polishing, is released as an ion in proportion to the polishing amount in the slurry after the polishing process.

Therefore, we presume that the polishing amount can be precisely measured by measuring the amount of free metal ions in the processed abrasive slurry.

On the other hand, the reason why the polishing amount can also be determined by measuring the conductivity is considered as follows. When glass is polished in the polishing process, the glass component is mixed into the abrasive slurry. Then, the ions are released from the glass component and become free ions. Therefore, it is considered that the conductivity of the slurry increases due to the free ions.

Therefore, the following equation works.

(Amount of Polished Glass in Slurry) oc (Amount of Free Ions) oc (Conductivity)

Therefore, we presume that the polishing amount of glass can be calculated either from the amount of free metal ions or from the conductivity.

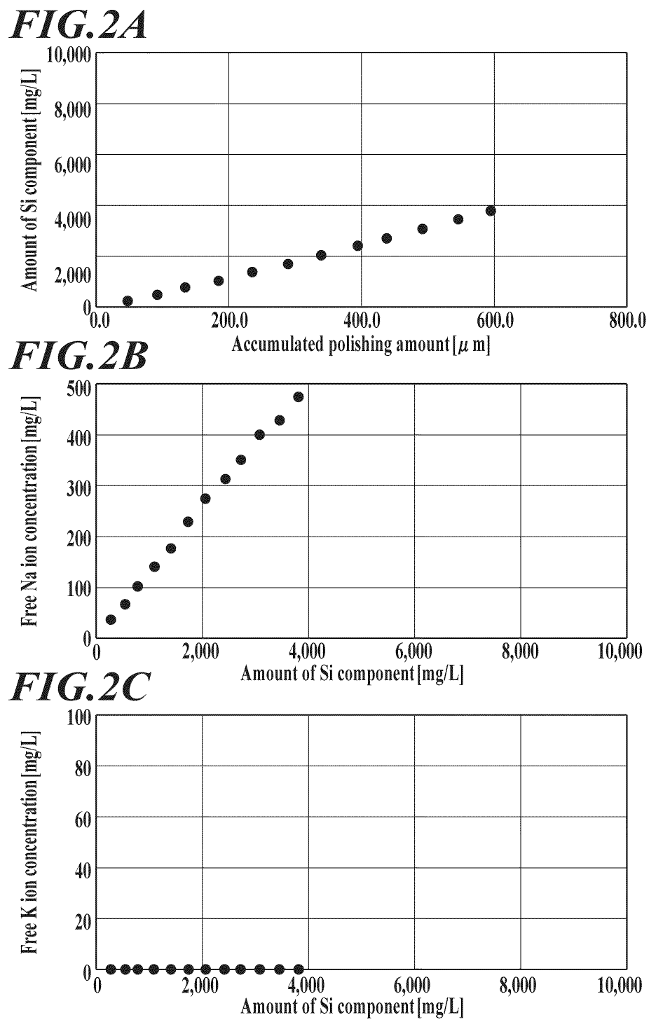

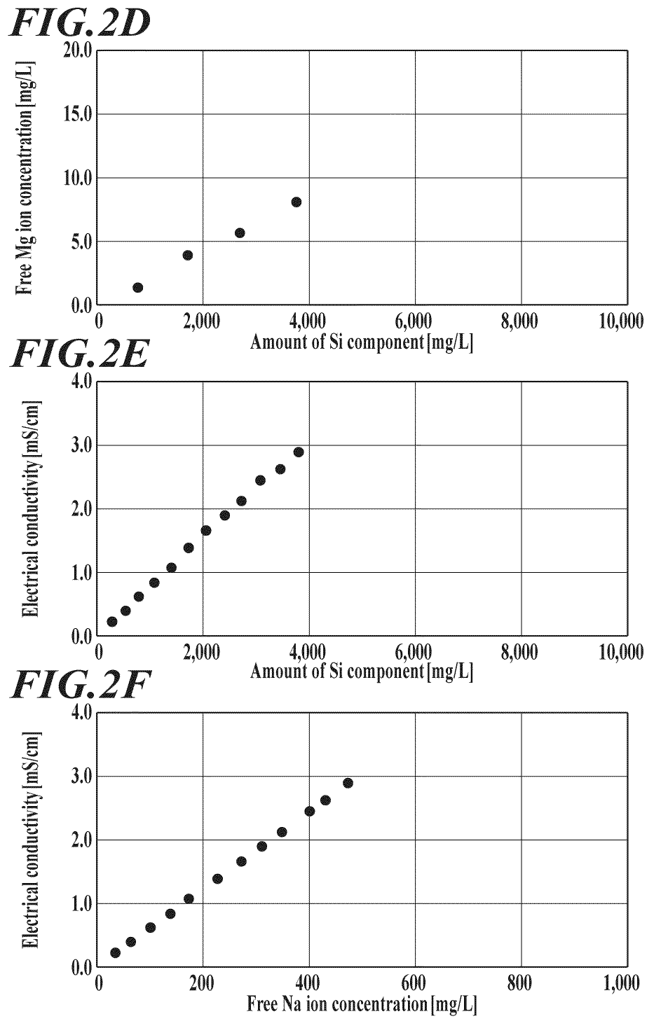

FIG. 2B shows an example of a polishing process of a Type 1 glass. Specifically, FIG. 2B shows an example of the relationship between the amount of a silicon component (Si component) in the abrasive slurry, that is, the polishing amount of the glass, and the concentration of free Na ions derived from the object to be polished in the abrasive slurry when the Type 1 glass (object to be polished that includes Na and includes SiO₂ as a major component described later) has been polished. Since the free Na ion concentration increases proportionally with the polishing amount of the glass, it is possible to precisely understand the amount of the glass that has been polished by measurement of the free Na ion concentration. Therefore, by measuring the free Na ion concentration. The details are described below.

Since the free metal ion concentration can be measured simply and quickly, it is possible to understand the polishing amount of the glass in real time during the polishing process, thereby reducing the variation of the polishing amount for each polishing process. In addition, it is possible to set the replacement timing of slurry based on the amount of the contained glass component, thereby reducing a deterioration of processing quality and the consumption of abrasive due to unnecessary replacement of the abrasive.

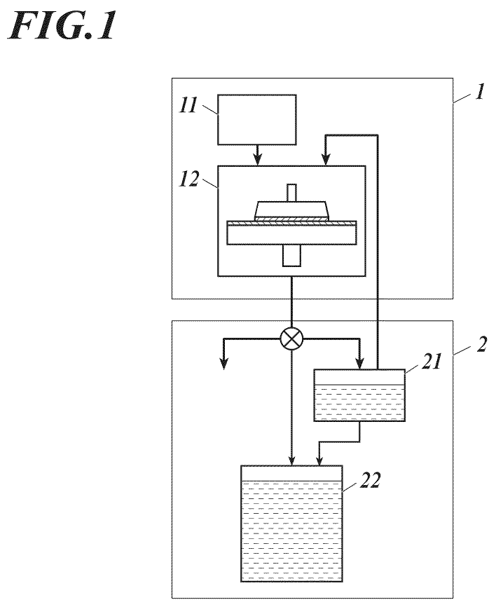

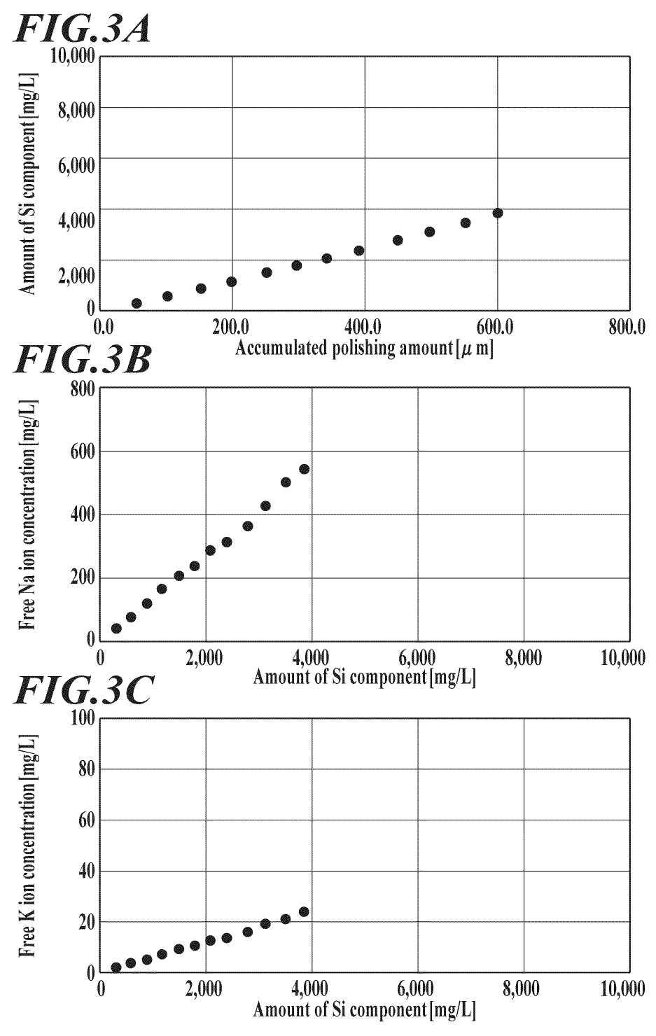

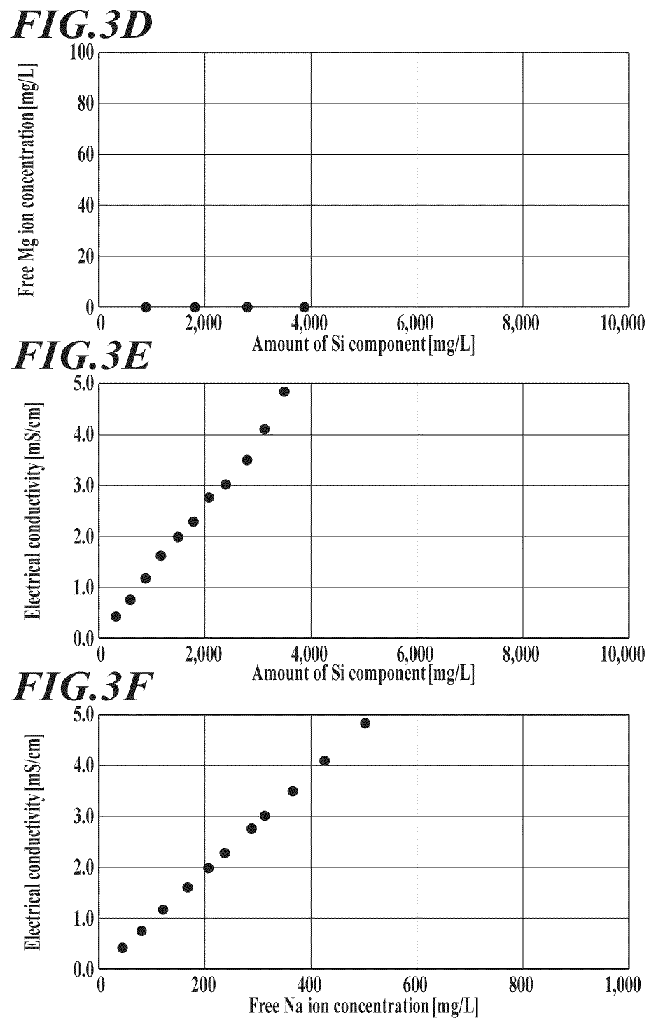

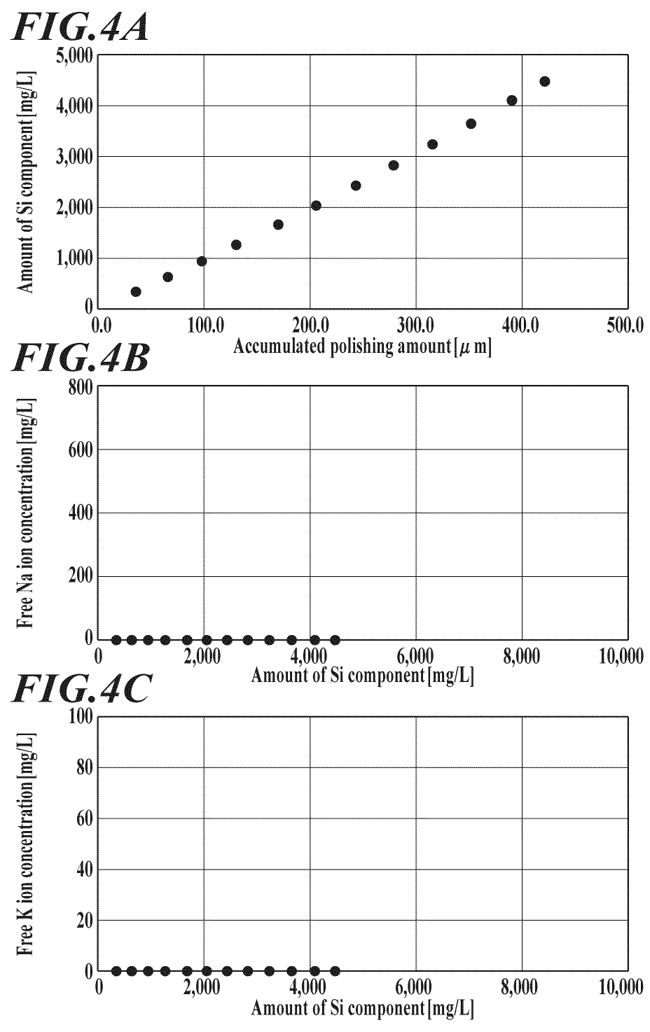

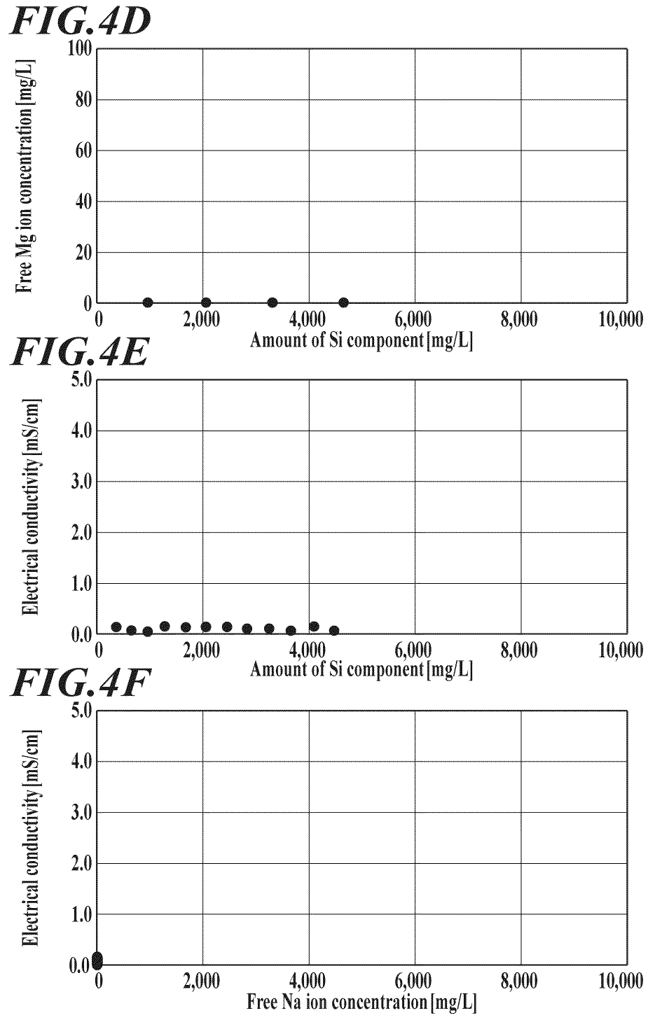

### BRIEF DESCRIPTION OF THE DRAWINGS

[FIG. 1] A schematic diagram of an example of a polishing system of the present invention

[FIG. 2A]Example of polishing process for Type 1 glass

[FIG. 2B]Example of polishing process for Type 1 glass

[FIG. 2C]Example of polishing process for Type 1 glass

[FIG. 2D]Example of polishing process for Type 1 glass

[FIG. 2E]Example of polishing process for Type 1 glass

[FIG. 2F]Example of polishing process for Type 1 glass

[FIG. 3A]Example of polishing process for Type 2 glass

[FIG. 3B]Example of polishing process for Type 2 glass

[FIG. 3C]Example of polishing process for Type 2 glass

[FIG. 3D]Example of polishing process for Type 2 glass

[FIG. 3E]Example of polishing process for Type 2 glass

[FIG. 3F]Example of polishing process for Type 2 glass

[FIG. 4A]Example of polishing process for Type 3 glass

[FIG. 4B]Example of polishing process for Type 3 glass

[FIG. 4C]Example of polishing process for Type 3 glass

[FIG. 4D]Example of polishing process for Type 3 glass

[FIG. 4E]Example of polishing process for Type 3 glass

[FIG. 4F]Example of polishing process for Type 3 glass

### DESCRIPTION OF EMBODIMENTS

The polishing system of the present invention performs chemical-mechanical polishing of an object to be polished using an abrasive slurry. The object to be polished is a glass containing a metallic element of Group 1 or 2 of the periodic table. The polishing system includes a polishing amount calculator that measures an amount of free metal ions of the metallic element derived from the object to be polished in a processed slurry and calculates a polishing amount of the object to be polished from the amount of the free metal ions. These are technical features common to or corresponding to each of the following embodiments (modes).

In the embodiments of the present invention, from the viewpoint of expressing the effect of the present invention, an endpoint of polishing is preferably determined based on the polishing amount of the object to be polished.

Also, from the viewpoint of expressing the effect of the present invention, the time of discarding the abrasive slurry is preferably determined based on the polishing amount of the object to be polished.

Furthermore, in the present invention, the free metal ions derived from the object to be polished are preferably free metal ions of a metallic element of Group 1 of the periodic table. The metallic element of Group 1 of the periodic table is preferred because it is easily released from the object to be polished (glass) and enables simple measurement of the free metal ion concentration or conductivity.

In the embodiments of the present invention, the free metal ions derived from the object to be polished are preferably sodium ions or potassium ions, because they are released from the glass in large quantities and can be detected easily.

The abrasive slurry preferably contains cerium oxide. This is preferred because the glass as the object to be polished is present in the slurry not as a solid but in a dissolved state or as a gel in response to chemical-mechanical polishing, which allows the metal ions contained in the glass to be easily released.

The polishing system of the present invention performs chemical-mechanical polishing of an object to be polished using an abrasive slurry. The object to be polished is a glass containing a metallic element of Group 1 or 2 of the periodic table. The polishing system includes a polishing amount calculator that measures a conductivity of a processed slurry and calculates a polishing amount of the object to be polished from the conductivity.

Hereinafter, the present invention, constituent elements thereof, and embodiments and modes for carrying out the present invention will be described in detail. In the present description, “to” is used to indicate that figures before and after “to” are included as a lower limit value and an upper limit value.

In the present invention, an “abrasive slurry” means a slurry collectively expressed as including the following various abrasive slurries depending on the polishing process. From the viewpoint of the polishing process, an “initial abrasive slurry” refers to a processing fluid at the initial stage of the polishing and contains an abrasive component and water and substantially no components constituting the object to be polished. A “processed abrasive slurry” refers to an abrasive slurry that contains components constituting the object to be polished.

In the present invention, the “chemical-mechanical polishing” means polishing that allows to obtain a smooth polished surface at high speed as a result of the increased mechanical polishing effect by the relative movements of the abrasive and the object to be polished, using the surface chemical action of the abrasive itself or the action of a chemical component in the abrasive slurry.

### Polishing System

The polishing system of the present invention performs chemical-mechanical polishing of an object to be polished using an abrasive slurry. The object to be polished is a glass containing a metallic element of Group 1 or 2 of the periodic table. The polishing system includes a polishing amount calculator that measures an amount of free metal ions of the metallic element derived from the object to be polished in a processed slurry and calculates a polishing amount of the object to be polished from the amount of the free metal ions.

FIG. 1 is a schematic diagram showing an example of the polishing system of the present invention. The polishing system of the present invention preferably includes a polishing processor 1 that performs a polishing process using a polishing machine 12, and an abrasive slurry collector 2 that has a slurry supply tank storing the abrasive slurry to be supplied to the polishing processor 1. After the polishing process, the processed abrasive slurry collected in the slurry supply tank 21 is supplied to the polishing machine 12 and used repeatedly in circulation. When the polishing amount reaches the limit, the processed abrasive slurry is replaced and discarded. The polishing system of the present invention includes a polishing amount calculator 3 (not shown) that measures the amount of free metal ions of the metallic element of Group 1 or Group 2 of the periodic table derived from the object to be polished in the abrasive slurry in this slurry supply tank 21 and calculates the polishing amount of the object to be polished from the amount of the free metal ions.

The amount of free metal ions may be measured by directly measuring the free metal ion concentration in the processed abrasive slurry in the slurry supply tank 21 using a measurement sensor, or by sampling an appropriate amount of the processed abrasive slurry in the slurry supply tank 21. The polishing amount of the object to be polished can be precisely and simply measured based on this measurement value and a previously prepared calibration curve of the polishing amount of the object to be polished and the amount of free metal ions. The polishing amount calculator 3 performs the process of precisely and simply measuring the polishing amount.

Instead of the free metal ion concentration, the polishing amount calculator 3 can measure the conductivity of the processed slurry in the same manner and calculate the polishing amount of the object to be polished from the conductivity.

### 1 Polishing Processor

One polishing processor 1 is preferably configured to perform the polishing process and washing of the polished parts.

### 1-1 Polishing Process

The polishing machine 12 of the polishing processor 1 preferably has a polishing surface plate to which a polishing cloth made of non-woven fabric, synthetic resin foam, or synthetic leather, or a polishing brush is attached. The polishing surface plate is preferably rotatable and includes an upper surface plate and a lower surface plate. During the polishing process, the object to be polished (for example, optical glass) is sandwiched between the upper surface plate and the lower surface plate and is pressed against the above polishing surface plate with a predetermined pressing force N using a holding tool, while the abrasive slurry is supplied and the polishing surface plates are rotated in opposite directions.

A polishing pad can be subject to pad dressing or pad brushing after continuous polishing. The pad dressing is a process to keep the pad condition constant by physically scraping and roughening the surface of the pad. Pad brushing, on the other hand, is a process to remove polishing debris, etc. contained in the uneven surface of the pad without scraping the pad.

Polishing process of one batch may also be performed using a plurality of polishing machines. In such a case, the variation of the processing time per batch for the next batch with respect to that for the previous batch is preferably 10% or less. Within this range, the variation of polishing processing time between a plurality of polishing machines can be suppressed. Here, one batch refers to a single unit of polishing process. For example, six glass substrates can be polished in one batch.

### 1-2 Washing

Immediately after polishing, a large amount of abrasive adheres to the glass substrate and the polishing machine. Therefore, it is preferable to supply water and the like from a washing water tank 11 instead of the abrasive slurry after polishing, and to spray the glass substrate and the polishing machine with water from spray nozzles to wash the adhering abrasive away. Specifically, the following sequence is preferred: start of polishing process (start of supplying abrasive slurry), end of polishing process (stop of supplying abrasive slurry: end of processing one batch), washing (supply of washing water), and end of washing (stop of washing water).

### 2 Abrasive Slurry Collector

The abrasive slurry collector 2 includes the slurry supply tank 21 that stores the abrasive slurry used for polishing and that can collect the processed abrasive slurry discharged from the system consisting of the polishing machine 12 and the wash water tank 11.

The abrasive slurry collector 2 may include, in addition to the slurry supply tank 21, a collected mixture fluid tank 22 that collects the abrasive slurry to be discarded.

The initial abrasive slurry prepared in advance in the slurry supply tank 21 is supplied to the polishing machine 12 with a pump as the polishing process starts and is collected in the slurry supply tank 21 after the polishing process has been completed. The abrasive slurry is repeatedly circulated between them during the polishing process.

Due to the polishing, the glass as the object to be polished is dissolved or gels in the abrasive slurry. As the concentration of Si component in the abrasive slurry increases, the abrasive slurry easily solidifies and becomes a contaminant in the abrasive slurry. Since the above contaminant causes defects such as scratches, the abrasive slurry containing the contaminant is not available. Therefore, it is necessary to measure the polishing amount precisely. Incorporating a process to remove precipitated solids of silicon oxide reduces the collection rate of the abrasive.

In the present invention, this problem is solved by the polishing amount calculator that measures the amount of free metal ions of a metallic element of Group 1 or Group 2 of the periodic table derived from the object to be polished in the processed slurry and calculates the polishing amount of the object to be polished from the amount of the free metal ions.

The processed slurry from which the amount of free metal ions is measured in the present invention is the abrasive slurry that is discharged out of the system of the polishing processor 1 including the polishing machine 12 and the washing water tank 11 after the polishing process and stored in the slurry supply tank 21.

### 3 Polishing Amount Calculator

The polishing amount calculator 3 measures the amount of the free metal ions of the metal element of Group 1 or Group 2 of the periodic table derived from the object to be polished in the processed slurry and measures the polishing amount of the object to be polished from the amount of the free metal ions.

Specifically, the polishing amount calculator 3 includes a measuring device that measures the amount of free metal ions. The polishing amount of the object to be polished is then calculated from the amount of free metal ions. A sensor may be provided directly in the slurry supply tank 21 and the measuring device may be integrated with the abrasive slurry collector 2, for example, together with the measuring sensor. Alternatively, the amount of free metal ions may be measured from an appropriate amount of the processed abrasive slurry sampled from the slurry supply tank 21.

The free metal ion concentration or conductivity of the processed abrasive slurry in the slurry supply tank 21 can be measured at the start of polishing and at the end of polishing described in the “Washing” section above, to exclude the effect of washing water contamination on the ion concentration.

The measured sample can be discarded in the procedure after sampling. Since the volume required for the measurement is about 5 mL, the precision of the measurement is not considered to be significantly affected.

In order to eliminate the effect of the washing water, the specific gravity of the slurry and the change in water level can be measured together to understand the amount of washing water added to the slurry. Thus, by taking the change in ion concentration due to the addition of the washing water into account, the amount of ions generated as a result of polishing the glass can be understood, that is, the amount of the polished glass can be understood.

### Measurement of Free Metal Ion Concentration in Processed Slurry and Conductivity

The concentration of free metal ions can be measured using a measuring device that measures ion concentration and conductivity (electrical conductivity), as described below.

The following measuring devices and the like can be used to measure free metal ion concentration and conductivity (also referred to as “electrical conductivity”).

Compact conductivity meter: LAQUA twin B-771 (manufactured by HORIBA, Ltd.)

Compact sodium ion meter: LAQUA twin, Na-11 (manufactured by HORIBA, Ltd.)

Compact potassium ion meter: LAQUA twin, K-11 (manufactured by HORIBA, Ltd.)

A sampling sheet is preferably used in the measurement of ion concentrations.

Sampling sheet: Sampling sheet B, Y046 (manufactured by HORIBA, Ltd.)

### Calculation Method of Polishing Amount of Glass From Free Metal Ion Concentration or Conductivity

The amount of ionic component released from the polished glass depends on the type of the glass to be polished.

The method to calculate the amount of glass component in the slurry is described below.

(1) For each object to be polished, the correlation between the polishing amount, slurry volume, and free metal ion concentration is evaluated in advance, and a calibration curve is prepared in advance.

By measurement of the free metal ion concentration in the slurry after the polishing process and check of the calibration curve, the amount of glass component in the slurry can be understood.

Instead of the above-mentioned measurement of the free metal ion concentration, the polishing amount can also be understood by measurement of conductivity, which is in proportion to the free metal ion concentration. Also in this case, it is necessary to prepare a calibration curve of the polishing amount and the electrical conductivity for each glass type in advance.

### Abrasive Slurry

The polishing system performs chemical-mechanical polishing of the object to be polished using an abrasive slurry.

Both physical and chemical actions are used in the chemical-mechanical polishing, such that a processing speed can be sufficient while a highly precise flatness is maintained in the polishing process of semiconductor substrate surface, glass, and the like.

To perform the chemical-mechanical polishing, either the surface chemical action of the abrasive itself or the action of a chemical component in the abrasive slurry may be used.

In performing the chemical mechanical polishing using the action of the chemical component, potassium hydroxide, sodium hydroxide, and ammonia can be used as the chemical component, and a polishing system using potassium hydroxide and colloidal silica can be used, for example. However, from the viewpoint of excluding changes in free metal ion concentration and conductivity due to added chemical component, the abrasive slurry of the present invention is preferably one including an abrasive having the surface chemical action.

The abrasive slurry can also contain additives such as dispersants as needed.

### Abrasive

Cerium oxide is preferably included as an abrasive having the surface chemical action.

The commonly used cerium oxide (for example, manufactured by SHOWA DENKO K.K., Techno Rise Corporation, and Mitsui Mining & Smelting Co., Ltd.) is not pure cerium oxide, but what is called bastnaesite, which is obtained by calcining and then grinding ores containing a high concentration of rare earth elements. Although cerium oxide is the main component, rare earth elements such as lanthanum, neodymium, and praseodymium are contained as other components, and fluoride and the like may also be included other than oxides.

The abrasive used in the present invention is highly effective and preferred when the above-mentioned abrasive component is included by 50% by mass or more.

The particle diameter of the abrasive is preferably in the range of 0.1 to 5.0 µm, depending on the flatness of the target object to be polished.

The abrasive is preferably dispersed in water in the range of 0.1 to 20% by mass.

### Dispersion of Abrasive

In order for the abrasive slurry to exhibit chemical-mechanical polishing effects, the abrasive particles are preferably dispersed in the slurry. The abrasive particles in the slurry may be dispersed by adding a dispersant or by processing with a dispersing machine.

Known dispersants such as acrylic acid-maleic acid copolymers can be used as a dispersant. A dispersing machine can be used to stably disperse the abrasives in the abrasive slurry.

### Object to Be Polished

In the present invention, the object to be polished is a glass including a metallic element of Group 1 or Group 2 of the periodic table. The object to be polished is preferably a glass containing a metallic element of Group 1 or Group 2 of the periodic table, and more preferably a glass containing a Na element or a K element from the viewpoint of measuring the metal ion component released from the glass.

From the viewpoint of measuring the metal ion component released from the glass, the content of the metallic element of Group 1 or Group 2 of the periodic table is preferably in the range of 1% by mass or more of the entire glass.

According to the present invention, the polishing amount of the object to be polished can be measured with high precision. Therefore, the present invention is suitable for polishing that requires precise polishing and can be preferably applied to polishing of optical glass such as a photomask, a lens, and a prism, a glass substrate for a magnetic disk, and cover glass for a smartphone, an in-vehicle display, and the like.

### Example

The present invention will be specifically described with examples below but is not limited to these examples. In the examples, “part” or “%” is used to indicate “part by mass” or “% by mass” unless otherwise noted.

### Object to Be Polished

Details of three types of glass, Types 1 to 3, used as the objects to be polished in the following examples are shown below.

TABLE 1

| Type of glass | | Type 1 | Type 2 | Type 3 |
|---|---|---|---|---|
| Composition [mass %] | SiO₂ | 60 | 60 | 99 |
| | Na₂O | 12 | 13 | 0 |
| | K₂O | 0 | 2 | 0 |
| | MgO+CaO | 2 | 0 | 0 |
| | Other | 26 | 25 | 1 |
| Size [mm] | Length | 150 | 150 | 150 |
| | Width | 80 | 80 | 80 |
| | Thickness | 1.1 | 1.1 | 1.1 |

Type 1: An object to be polished including SiO₂ as a main component, with Na, Mg and Ca as metallic elements of Group 1 or Group 2 of the periodic table.

The mass ratio of MgO to CaO (MgO/CaO) is 3.

Type 2: An object to be polished including SiO₂ as a main component, with Na and K as metallic elements of Group 1 or Group 2 of the periodic table.

Type 3: An object to be polished including SiO₂ as a main component, without metallic elements of Group 1 or Group 2 of the periodic table.

The amount (% by mass) of each component shown in the table is when it is converted to an oxide.

### Example 1

### Preparation of Abrasive Slurry

Cerium oxide particles (MIREK E21: manufactured by Mitsui Mining & Smelting Co., Ltd.) were dispersed in water, and 50 liters of slurry with a specific gravity of 1.15 were prepared, which was used as the initial abrasive slurry.

### Polishing Process

By using the polishing system of the present invention shown in FIG. 1, the 50 liters of the prepared initial abrasive slurry was stored in the slurry supply tank 21 of the abrasive slurry collector 2.

In the polishing processor 1, the above glass was brought into contact with the polishing cloth, was moved relative to the polishing pad while the abrasive slurry was supplied from the slurry supply tank 21 and pressure was applied to the contact surfaces and started to be polished. Thirty five pieces of glass were polished in one process (one batch). The polishing process was performed while the abrasive slurry was supplied to the polishing machine in a circulating manner so that the polishing amount for each piece of glass corresponds to a thickness of about 50 µm. The polishing process was repeated for a total of 12 times.

### Measurement of Polishing Amount, Concentration of Metallic Element, and Conductivity

The polishing amount was measured for each process. The polishing amount (thickness) was measured from each of 10 out of 35 pieces of the glass, and the arithmetic average of the measured values was used as the polishing amount for each polishing process.

Similarly, 5 mL of the processed abrasive slurry was sampled after each process, and the amount of Si component in the abrasive slurry, the free metal ion concentrations of Na, K, Mg, and Ca, and the conductivity of the slurry at 25° C. were measured.

Of the concentrations of the above elements, Na concentration was measured using a compact sodium ion meter (manufactured by HORIBA, Ltd.) and K concentration was measured using a compact potassium ion meter (manufactured by HORIBA, Ltd.), using sampling sheets (manufactured by HORIBA, Ltd.) in each measurement.

Mg and Ca concentrations were measured using filtration of the sampled slurry through a PTFE membrane filter with a pore size of 0.2 µm and then the ICP Atomic Emission Spectroscopy of the filtrate described above.

The amount of Si component was measured from the sampled slurry using ICP atomic emission spectrometry as described above.

Conductivity was measured with a compact conductivity meter (LAQUA twin B-771: manufactured by HORIBA, Ltd.). The total volume of the abrasive slurry gradually decreased due to sampling and evaporation of water.

### Results of Evaluation

The above results are shown in Tables II to IV. In the following tables, “-” in the column of free Mg ion concentration indicates that measurement was not performed.

FIG. 2A to FIG. 4F shows the amount of Si component against the accumulated polishing amount, free metal ion concentrations of Na, K, and Mg against the amount of Si component, and conductivity (conductivity against free Na ion concentration) for the polishing processes of each of the Type 1 to 3 glasses based on Tables II to IV. FIG. 2A to FIG. 2F are polishing process examples of Type 1 glass. FIG. 3A to FIG. 3F are polishing process examples of Type 2 glass. FIG. 4A to FIG. 4F are polishing process examples of Type 3 glass.

TABLE 2

Type of glass Type 1

| Number of polishing processes | Polishing amount [µ m] | Accumulated polishing amount [µ m] | Amount of Si component [mg/L] | Free Na ion concentration [mg/L] | Free K ion concentration [mg/L] | Free Mg ion concentration [mg/L] | Electrical conductivity [mS./cm] |
|---|---|---|---|---|---|---|---|
| 1 | 48.5 | 48.5 | 276 | 36 | 0 | – | 0.2 |
| 2 | 44.7 | 93.1 | 536 | 65 | 0 | – | 0.4 |
| 3 | 41.4 | 134.5 | 733 | 102 | 0 | 1.4 | 0.6 |
| 4 | 50.1 | 184.7 | 1,086 | 139 | 0 | – | 0.8 |
| 5 | 51.3 | 236.0 | 1,402 | 175 | 0 | – | 1.1 |
| 6 | 53.5 | 289.4 | 1,738 | 228 | 0 | 3.9 | 1.4 |
| 7 | 49.9 | 339.4 | 2,060 | 274 | 0 | – | 1.7 |
| 8 | 5.7 | 395.0 | 2,424 | 312 | 0 | – | 1.9 |
| 9 | 43.2 | 438.2 | 2,718 | 350 | 0 | 5.7 | 2.1 |
| 10 | 52.9 | 491.1 | 3,080 | 401 | 0 | – | 2.4 |
| 11 | 54.1 | 545.2 | 3,458 | 429 | 0 | – | 2.6 |
| 12 | 48.9 | 594.1 | 3,811 | 474 | 0 | 8.1 | 2.9 |

TABLE 3

Type of glass Type 2

| Number of polishing processes | Polishing amount [µ m] | Accumulated polishing amount [µ m] | Amount of Si component [mg/L] | Free Na ion concentration [mg/L] | Free K ion concentration [mg/L] | Free Mg ion concentration [mg/L] | Electrical conductivity [mS/cm] |
|---|---|---|---|---|---|---|---|
| 1 | 55.1 | 55.1 | 314 | 44 | 2 | – | 0.4 |
| 2 | 47.0 | 102.1 | 588 | 79 | 4 | – | 0.8 |
| 3 | 50.3 | 152.4 | 887 | 122 | 5 | <0.1 | 1.2 |
| 4 | 45.9 | 198.3 | 1,166 | 167 | 7 | – | 1.6 |
| 5 | 53.0 | 251.4 | 1,493 | 207 | 9 | – | 2.0 |
| 6 | 46.00 | 297.4 | 1,786 | 237 | 11 | 0.1 | 2.3 |
| 7 | 44.7 | 342.1 | 2,076 | 288 | 13 | – | 2.8 |
| 8 | 48.6 | 390.7 | 2,397 | 314 | 14 | – | 3.0 |
| 9 | 58.9 | 449.5 | 2,788 | 365 | 16 | 0.1 | 3.5 |
| 10 | 47.5 | 497.0 | 3,117 | 427 | 19 | – | 4.1 |
| 11 | 54.1 | 551.1 | 3,495 | 503 | 21 | – | 4.8 |
| 12 | 50.4 | 601.5 | 3,858 | 542 | 24 | 0.2 | 5.2 |

TABLE 4

Type of glass Type 3

| Number of polishing processes | Polishing amount [µ m] | Accumulated polishing amount [µ m] | Amount of Si component [mg/L] | Free Na ion concentration [mg/L] | Free K ion Free Mg ion concentration concentration : [mg/L] [mg/L] | | Electrical conductivity [mS/cm] |
|---|---|---|---|---|---|---|---|
| 1 | 35.9 | 35.9 | 338 | 0 | 0 | – | 0.1 |
| 2 | 30.4 | 66.3 | 630 | 0 | 0 | – | 0.1 |
| 3 | 32.1 | 98.4 | 945 | 0 | 0 | 0.1 | 0.1 |
| 4 | 32.4 | 130.8 | 1,269 | 0 | 0 | – | 0.1 |
| 5 | 39.5 | 170.2 | 1,669 | 0 | 0 | – | 0.1 |
| 6 | 35.3 | 205.5 | 2,037 | 0 | 0 | 0.1 | 0.1 |
| 7 | 38.0 | 243.6 | 2,439 | 0 | 0 | – | 0.1 |
| 8 | 35.6 | 279.2 | 2,826 | 0 | 0 | – | 0.1 |
| 9 | 37.0 | 316.1 | 3,235 | 0 | 0 | 0.1 | 0.1 |
| 10 | 36.6 | 352.7 | 3,650 | 0 | 0 | – | 0.1 |
| 11 | 38.0 | 390.7 | 4,089 | 0 | 0 | – | 0.1 |
| 12 | 31.4 | 422.2 | 4,468 | 0 | 0 | 0.1 | 0.1 |

As for the objects to be polished of Type 1 and Type 2, it can be understood that the free metal ion concentrations of Na, K and Mg metal elements derived from the object to be polished, and the conductivity increase in proportion to the concentration of Si component (derived from the object to be polished) in the abrasive slurry that has been used in the polishing process. The free metal ion concentration of Ca similarly increased in proportion to the concentration of Si component (derived from the object to be polished) in the abrasive slurry.

On the other hand, as for the object to be polished of Type 3, no increase in the metal ion concentration or conductivity was observed even when the concentration of Si component (derived from the object to be polished) in the abrasive slurry that has been used in the polishing process increased.

It is considered that, during the polishing process of the object to be polished that includes alkali metal or alkaline earth metal ion component and includes SiO₂ as a major component, the included alkali metal component or alkaline earth metal ion component is released into the slurry, which results in an increase in the free metal ion concentration in the slurry and an increase in conductivity.

In other words, measurement of the free metal ion concentration or conductivity in the slurry enables calculation of the amount of Si component contained in the liquid.

However, the amount of free alkali metal ions or free alkaline earth metal ions and electrical conductivity vary depending on the type of glass used in the polishing process. Therefore, it is possible to simply and precisely measure the amount of Si component in the abrasive slurry, that is, the polishing amount, by evaluating the ion concentration or electrical conductivity using a calibration curve prepared in advance for each glass type and each polishing method.

Also, by determining an endpoint of polishing based on the obtained polishing amount, it is possible to efficiently perform the polishing process according to the purpose.

Similarly, by determining the time to discard the abrasive slurry based on the obtained policing amount, it is possible to efficiently perform the polishing process according to the purpose.

### Example 2

The glass of Type 1 after polishing was compared between the case in which polishing was performed while the time of the polishing process was adjusted with measurement of the free metal ion concentration (Example) and the case in which polishing was performed under constant polishing process conditions (Comparative Example).

### Polishing Process

The polishing process was performed by modifying the polishing method for Type 1 glass described in Example 1 as described below.

1. The volume of used abrasive slurry was 20 liters, and the abrasive slurry was fully replaced each time (one batch).

2. The polishing pad was brushed after each batch.

3. The polishing amount was set to 20 µm ± 2 µm (18 to 22 µm) as the specification value for the polishing process.

4. The number of polishing processes was set to 10 times, and 35 pieces of glass were polished at one time (one batch) (350 pieces in total).

5. The time of polishing process was changed as follows in Example and Comparative Example.

### Polishing in Example

In Example, every five minutes during the polishing process, the free Na ion concentration of the abrasive slurry was measured, the polishing amount of the object to be polished was calculated from the relationship between the polishing amount (thickness) and the free Na ion concentration, which was obtained in Example 1, and the polishing process time for each batch was adjusted.

### Polishing in Comparative Example

In Comparative Example, first, the process was performed for different processing times, such as 30, 35, 40, 45, and 50 minutes, and the processing time to obtain a thickness of 20 µm after polishing was determined to be 36 minutes. Then, each polishing was performed for a fixed processing time of 36 minutes.

### Evaluation

All 350 pieces of the polished glass in the Example and Comparative Example were each evaluated for the polishing amount (thickness) and scratch/bum.

The polishing amount was evaluated by examining the thickness of each of all pieces of glass before and after the process. A piece of glass with a polishing amount within the set range was evaluated as good, and a piece of glass with a polishing amount outside the set range was evaluated as a defective product. In the polishing of Comparative Example, an arithmetic average of polishing amounts of respective pieces of glass after polishing was calculated for each batch and shown in the TABLE as the average polishing amount.

As for the occurrence of scratches and burns, all pieces of glass were evaluated visually after the process.

Scratches were evaluated by visual inspection of the surface of each piece of glass after the polishing process while illuminating with a condensing lamp in a darkened room. A piece of glass with a visible scratch on the surface was evaluated as good, and a piece of glass with no visible scratch was evaluated as a defective product.

Burns, such as white burns and blue burns, were determined by visually inspecting the glass after the polishing process. A piece of glass with no visible burn was evaluated as good, and a piece of glass with a burn was evaluated as a defective product.

The evaluation results are shown in Tables V and VI. In Tables V and VI, the number of defective products is shown. The number of defective products for scratches and burns are shown as a total.

TABLE 5

Example: Polishing time is adjusted depending on free Na ion concentration

| Number of Polishing Processes | Number of d defective products | |
|---|---|---|
| | Thickness | Scratches, burns |
| 1 | 1 | 0 |
| 2 | 0 | 0 |
| 3 | 1 | 0 |
| 4 | 2 | 1 |
| 5 | 0 | 0 |
| 6 | 0 | 1 |
| 7 | 1 | 1 |
| 8 | 3 | 0 |
| 9 | 0 | 2 |
| 10 | 1 | 3 |
| Total | 9 | 8 |

TABLE 6

Comparative example: Polishing time is constant.

| Number of Polishing Processes | Number of defective products | | Polishing time. [min] | Average polishing amount [µ m] |
|---|---|---|---|---|
| | Thickness | Scratches, burns | | |
| 1 | 1 | 0 | 36 | 20.0 |
| 2 | 18 | 0 | 36 | 21.9 |
| 3 | 1 | 0 | 36 | 20.6 |
| 4 | 30 | 1 | 36 | 17.6 |
| 5 | 1 | 0 | 36 | 20.2 |
| 6 | 35 | 1 | 36 | 23.4 |
| 7 | 1 | 0 | 36 | 19.4 |
| 8 | 35 | 1 | 36 | 16.2 |
| 9 | 6 | 2 | 36 | 18.6 |
| 10 | 1 | 1 | 36 | 19.1 |
| Total | 129 | 6 | | |

From Tables V and VI, it can be understood that the straight yield was higher in Example than in Comparative Example. While the number of defective products after polishing in Comparative Example was 135, or 38.6% in terms of percentage, the number of defective products after polishing in Example was 17, or 4.9% in terms of percentage.

From Comparative Example, it can be understood that precise control of the polishing amount is difficult even when the polishing time is kept constant. Highly precise polishing is realized by measuring the amount of free metal ions, calculating the polishing amount of the object to be polished from the amount of free metal ions and adjusting the polishing time.

### INDUSTRIAL APPLICABILITY

According to the polishing system of the present invention, the polishing amount of the object to be polished can be measured with high precision. Therefore, the polishing system is suitable for polishing that requires precise polishing and can be preferably applied to polishing optical glass such as a photomask, a lens, and a prism, a glass substrate for a magnetic disk, and a cover glass for a smartphone, an in-vehicle display, and the like.

REFERENCE SIGNS LIST

| | |
|---|---|
| 1 | Polishing Processor |
| 2 | Abrasive Slurry Collector |
| 11 | Washing Water Tank |
| 12 | Polishing Machine |
| 21 | Slurry Supply Tank |

1. A polishing system that performs chemical-mechanical polishing of an object to be polished using an abrasive slurry, the polishing system comprising:
a polishing amount calculator that measures an amount of free metal ions of a metallic element derived from the object to be polished in a processed slurry and calculates a polishing amount of the object to be polished from the amount of the free metal ions,
wherein the object to be polished is a glass containing the metallic element of Group 1 or Group 2 of a periodic table.

2. The polishing system according to claim 1, wherein an endpoint of polishing is determined based on the polishing amount of the object to be polished.

3. The polishing system according to claim 1, wherein a time of discarding the abrasive slurry is determined based on the polishing amount of the object to be polished.

4. The polishing system according to claim 1, wherein the free metal ions derived from the object to be polished are free metal ions of a metallic element of Group 1 of the periodic table.

5. The polishing system according to claim 1, wherein the free metal ions derived from the object to be polished are sodium ions or potassium ions.

6. The polishing system according to claim 1, wherein the abrasive slurry contains cerium oxide.

7. A polishing system that performs chemical-mechanical polishing of an object to be polished using an abrasive slurry, the polishing system comprising:
a polishing amount calculator that measures a conductivity of a processed slurry and calculates a polishing amount of the object to be polished from the conductivity,
wherein the object to be polished is a glass containing a metallic element of Group 1 or Group 2 of a periodic table.
